(19) United States
(12) Patent Application Publication
(10) Pub. No.: US 2023/0124098 A1
(43) Pub. Date: Apr. 20, 2023

(54) SEMICONDUCTOR PACKAGE WITH WARPAGE CONTROL

(71) Applicant: Intel Corporation, Santa Clara, CA (US)

(72) Inventors: Chin Lee Kuan, Bentong (MY); Bok Eng Cheah, Gelugor (MY); Jackson Chung Peng Kong, Tanjung Tokong (MY)

(21) Appl. No.: 17/503,413

(22) Filed: Oct. 18, 2021

(51) Int. Cl. H01L 23/00; H01L 23/552; H01L 23/498; H01L 21/48

(52) U.S. Cl. CPC H01L 23/562; H01L 23/552; H01L 23/49816; H01L 21/481

(57) ABSTRACT

The present disclosure is directed to a semiconductor package including: a package substrate including a top surface, lateral sides and a bottom surface; a ball grid array including a plurality of solder balls coupled to the bottom surface; a stiffener including a bottom portion affixed to the bottom surface of the package substrate and a lateral portion extending from the bottom portion and affixed to the lateral sides of the package substrate, the bottom portion of the stiffener including a plurality of openings for the plurality of solder balls, wherein the top surface of the package substrate is substantially flush with a top surface of the lateral portion; and an electronic component coupled to the top surface of the package substrate.

### BACKGROUND

As the form-factor of semiconductor packages continues to shrink to achieve system miniaturization for personal computing devices, the silicon device height and footprint need to be scaled adequately. The reduction in thickness may lead to mechanical warpage concerns, especially for advanced 2.5D electronic semiconductor packages with silicon interposers.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A illustrates a side view of a conventional semiconductor package;

FIG. 1B illustrates a side view of a conventional semiconductor package;

FIG. 2 illustrates a side view of a semiconductor package in accordance with an aspect of the disclosure;

FIG. 3 illustrates a side view of a semiconductor package in accordance with an aspect of the disclosure;

FIG. 4 illustrates a side view of a semiconductor package in accordance with an aspect of the disclosure;

FIG. 5 illustrates a side view of a semiconductor package in accordance with an aspect of the disclosure;

FIG. 6 illustrates a bottom view of a semiconductor package in accordance with an aspect of the disclosure;

FIG. 7 illustrates a side view of a semiconductor package in accordance with an aspect of the disclosure;

FIG. 8 illustrates a side view of a semiconductor package in accordance with an aspect of the disclosure;

FIG. 9A to FIG. 9G illustrates a process for making the semiconductor package in accordance with an aspect of the disclosure;

FIG. 10 shows a simplified flow diagram for an exemplary method for making semiconductor packages according to an aspect of the present disclosure; and

FIG. 11 shows an illustration of a computing device that includes a present semiconductor package according to a further aspect of the present disclosure.

### DETAILED DESCRIPTION

Combining multiple integrated circuit dies in a single semiconductor package without stacking them into a three-dimensional integrated circuit (3D-IC) with through-silicon vias (TSVs) is commonly referred to as a 2.5D stacked integrated circuit (2.5D IC). In this kind of semiconductor package, many of the advantages of 3D integration can be approximated by placing silicon dies and/or chiplets side by side on an interposer instead of stacking them vertically. If the pitch is very fine and the interconnect very short, the assembly can be packaged as a single component with better size, weight, and power characteristics than a comparable 2D package or circuit board assembly. A problem encountered in such semiconductor packages is a lack of warpage control.

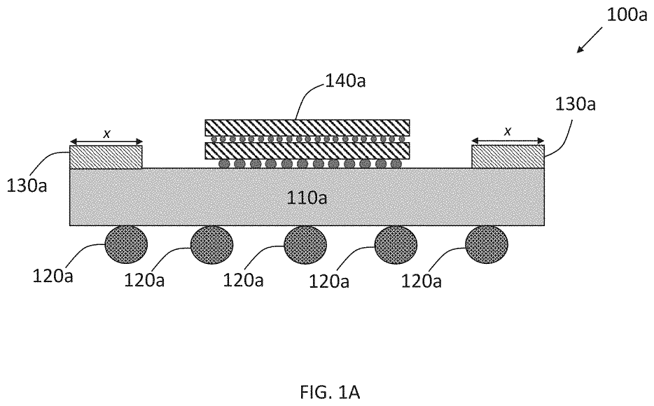

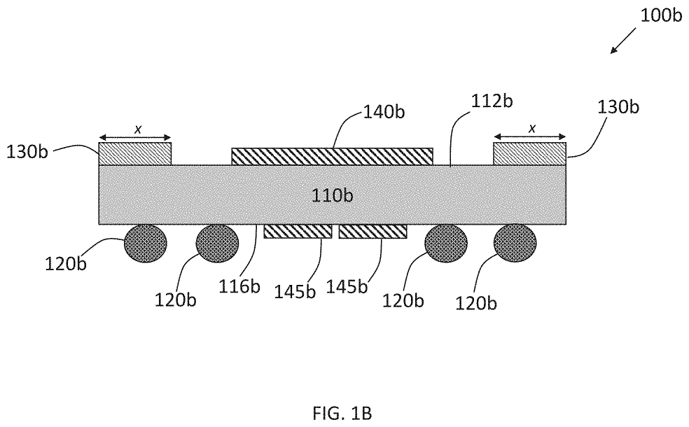

A previous attempt to improve the warpage control for a semiconductor package 100 includes the placement of metal stiffeners on the top side of the semiconductor package periphery as depicted, for example, in FIG. 1A and FIG. 1B. However, a disadvantage associated with this approach includes problems with the placement of decoupling components, e.g., die-side capacitors (for power delivery noise mitigation), due to constrained package top side footprint for placement, thus restricting package power delivery decoupling solution to the landside capacitors. This leads to ball grid array (BGA) density trade-off and/or package footprint expansion.

Another attempt to improve warpage control for 2.5D semiconductor packages includes an increase in package substrate core thickness and/or BGA dimension for warpage control. However, this modification is also associated with device form-factor (and/or real-estate) and signal integrity trade-off ascribed to impedance discontinuities and/or crosstalk coupling with the extended plated through hole and BGA pad structures.

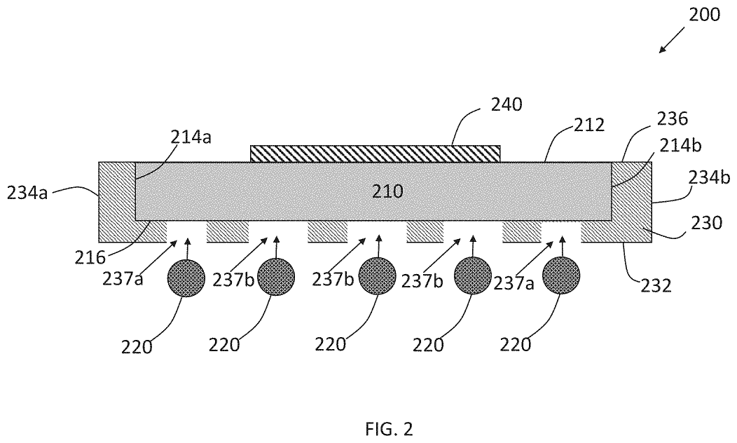

To address these shortcomings, with regard to an aspect as illustrated in FIG. 2, there is disclosed a semiconductor package 200 including: a package substrate 210 including a top surface 212, lateral sides 214 and a bottom surface 216; a ball grid array including a plurality of solder balls 220 arranged on the bottom surface 216; a stiffener 230 including a bottom portion 232 affixed to the bottom surface 216 of the package substrate 210 and a lateral portion 234 extending from the bottom portion 232 and disposed about a lateral side 214 of the package substrate 210 such that the top surface 212 of the package substrate 210 is substantially flush with a top surface 236 of the lateral portion 234; and an electronic component 240 coupled to the top surface 212 of the package substrate 210.

Advantageously, since the stiffener 230 is disposed over substantially the entire breadth of the bottom portion 216 of the package substrate 100, the contact surface area between the stiffener 230 and the package substrate 100 is increased, compared to the semiconductor packages 100a, 100b of the prior art as depicted in FIG. 1A and FIG. 1B, where the stiffener 130a, 130b is disposed only on parts of the top surface of the package substrate 110a, 110b, since the remaining space is required for placement of the electronic component 140a, 140b. This increased stiffener contact surface area results in improved warpage control, without compromising system form-factor, z-height and electrical (power and signal integrity) performance.

Moreover, since the stiffener 130b is using up the space for placement on the top surface 112b of the package substrate 100b, thereby wasting between 2 to 8 mm of placement space (indicated as “x” in FIG. 1A and FIG. 1B), it may become necessary to attach passive components, e.g., capacitor 145b, on the bottom surface 116b of the package substrate 100b. In contrast, when the stiffener 230 is attached to the lateral sides 214 and a bottom surface 216 of the package substrate 200, package form-factor can be reduced through avoidance of a cavity or keep-out-zone in the bottom surface 216 that would otherwise be necessary for the placement of the passive component.

The semiconductor package 200 furthermore has the advantage of having an improved signal integrity, e.g., improved channel impedance matching through reduced vertical plated through hole thickness and miniaturized solder ball interconnects and associated contact pads, and enhanced BGA crosstalk shielding by using the extended stiffener portion of stiffener 230.

The semiconductor package 200 furthermore has the advantage of being able to mitigate the AC power noise for Vₘᵢₙ improvements and impedance loadline reduction, thereby contributing to reduced power supply induced jitter noise and computing core and/or graphics Fₘₐₓ performance gain.

The package substrate 210 may include typical substrate materials. For example, the package substrate 210 may include an epoxy-based laminate substrate having a core layer for mechanical support and/or build-up layers. In one aspect, the package substrate 210 may include a coreless substrate i.e., an epoxy-based laminate substrate and/or build-up layers without a rigid core layer. The package substrate 210 may include other suitable types of substrates in other aspects. For example, the package substrate 210 may include any suitable semiconductor material (e.g., a silicon, gallium, indium, germanium, or variations or combinations thereof, among other substrates), one or more insulating layers, such as glass-reinforced epoxy, such as FR-4, polytetrafluoroethylene, cotton-paper reinforced epoxy, phenolic-glass, paper-phenolic, polyester-glass, Ajinomoto Build-up Film, any other dielectric material, such as bismaleimide-triazine epoxy resin, or any combination thereof, such as can be used in electronic package substrate and/or printed circuit boards (PCBs).

An electronic component can be any electronic device or component that may be included in a semiconductor package, such as a semiconductor device (e.g., a die, a chip, a processor, computer memory, a platform controller hub, etc.). In one aspect, the electronic component 240 may represent a discrete chip. The electronic component 240 may include, or be a part of a processor (e.g., a CPU, a GPU, etc.), a memory device (e.g., SRAM, DRAM, flash memory, EEPROM, etc.), an application specific integrated circuit, a platform controller hub, a field programmable gate array, a system on a chip, a 3D-IC stack, a neural network accelerator, a system in a package, or a package on a package in some aspects. Although one electronic component 240 is depicted in FIG. 2, any suitable number of electronic components can be included.

The electronic component 240 can be attached to the substrate 210 according to a variety of suitable configurations including a flip-chip configuration, wire bonding, and the like. The electronic component 240 can be electrically coupled to the substrate 210 using interconnect structures (e.g., solder balls and/or wire bonds, not shown) configured to route electrical signals between the electronic component 240 and the package substrate 210. In some aspects, the interconnect structures may be configured to route electrical signals such as, for example, I/O signals and/or power or ground networks associated with the operation of the electronic component 240.

The package substrate 210 may include electrically conductive elements or electrical routing features (not shown) configured to route electrical signals to or from the electronic component 240. The electrical routing features may be internal (e.g., disposed at least partially within a thickness of the package substrate 210) and/or external to the package substrate 210. For example, in some aspects, the package substrate 210 may include electrical routing features such as pads, vias, and/or traces configured to receive the interconnect structures and route electrical signals to or from the electronic component 240. The pads, vias, and traces can be constructed of the same or similar electrically conductive materials, or of different electrically conductive materials. The semiconductor package 200 also includes interconnects, such as solder balls 220, for coupling with a substrate (e.g., a circuit board such as a motherboard, not shown) for power supply, ground termination and/or signaling. The plurality of solder balls 220 is disposed in a BGA and the stiffener 230 may extend into a BGA for enhanced mechanical performance. The BGA is an area or zone (e.g., a “footprint”) on the bottom surface 216 of the package substrate 210 where the solder balls 220 are disposed. It should be recognized that the BGA can have any suitable shape or configuration.

The stiffener 230 can be affixed (i.e., mechanically coupled or otherwise attached) to the package substrate 210 in any suitable manner. The stiffener 230 may have a bottom portion 232 affixed to the bottom surface 216 of the package substrate 210. The bottom portion 232 of the stiffener 230 can have a first opening 237a and a second opening 237b to accommodate the plurality of solder balls 220. In some aspects, the plurality of solder balls 220 can extend at least partially through the first and second openings 237a, 237b.

The stiffener 230 can also have a lateral portion 234 extending from the bottom portion 232. The lateral portion 234 can be disposed about lateral sides 214a, 214b respectively, of the package substrate 210. The lateral portion 234 of the stiffener 230 can be in contact with the respective lateral sides 214a, 214b of the package substrate 210, which can enhance the coupling of the stiffener 230 and the package substrate 210 and therefore enhance the mechanical stiffness or rigidity of the stiffener/substrate combination. In one aspect, two lateral portions 234a, 234b can be disposed about opposite lateral sides 214a, 214b of the package substrate 210 to provide balanced reaction of forces and moments from the package substrate 210. In other words, such a symmetrical configuration of the stiffener 230 can serve to provide opposing forces and moments acting on the package substrate 210 that tend to resist warpage of the substrate 210.

The lateral portion 234 may extend to the same height as the package substrate 210. Hence, the lateral portion 234 and a top surface of the package substrate 212 may together form a surface that is substantially flush, e.g., it is coplanar to each other. A thickness of the lateral portion 234 may thus help to enlarge the total surface of the semiconductor package 200, thereby increasing space for placing electronic components 240 on the total surface of the semiconductor package 200.

The entire height of the lateral portion, including the bottom part of the bottom portion that contributes to the height of the lateral portion, may be ranging from approximately 0.4 mm to 1.2 mm.

In one aspect, the stiffener 230 is made of a material that may include a metal, e.g., an aluminum or stain-less steel. Alternatively, the material of the stiffener 230 may include an organic material that is coated with a metal, e.g., an epoxy mold with a conductive aluminum layer or an aluminum-copper composite layer. In one aspect, the organic mold may be reinforced with fiber glass for improved rigidity. In one aspect, the stiffener 230 may include a metal coated inorganic layer, e.g., a silicon or a glass substrate with conductive aluminum layer or an aluminum-copper composite layer. Accordingly, the stiffener 230 may be constructed of a metal material, a ceramic material, a polymer material, a composite material, or any combination thereof. Alternatively, the stiffener 230 may be constructed of a non-conductive base material that is electroplated with a metal.

A thickness of the stiffener 230 may be about 50 μm to about 500 μm. The thickness of the stiffener 230 may be, in one aspect, homogenous across the bottom portion 232 and the lateral portion 234. In another aspect, the thickness of the lateral portion 234 may be greater than the thickness of the bottom portion, e.g., with a ratio of 2:1. A higher thickness of the lateral portion 234 may be advantageous since the total surface of the semiconductor package for placement of electronic components may be increased by contribution from the stiffener 230. One the other hand, a thickness that is too high may require too much space (e.g., PCB keep-out-zone real estate) and be disadvantageous for overall device or system miniaturization. In one aspect, a beneficial balance between space requirement and stability may be achieved at a thickness in the range of about 200 μm to about 300 μm.

It is within the disclosure to affix the stiffener to the package substrate by using an adhesive, as shown, for example, in FIG. 5.

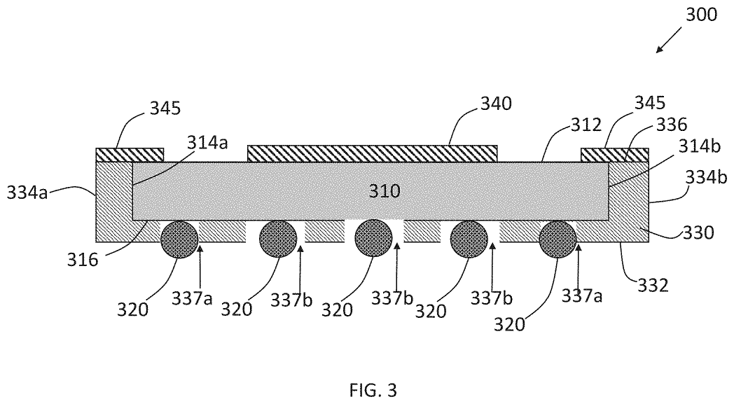

According to an aspect as illustrated in FIG. 3, the semiconductor package 300 may include components 310, 312, 314a, 314b, 316, 320, 330, 332, 334a, 334b, 336, 337a, 337b, 340 as analogously discussed for FIG. 2, wherein the electronic component 340 may include a passive component 345 that is disposed on the top surface 336 of the lateral portion 334 of the stiffener 330. The passive component 345 may be selected from the group consisting of an inductor, a capacitor, a resistor, a voltage regulator, or any combination thereof. Since the stiffener 330 is positioned on a bottom surface 316 and the lateral sides 314 of the package substrate 310, it is this possible to have sufficient space on a total surface of the semiconductor package 300 for the positioning of the passive component 345 thereon. The passive component 345 may be coupled to the stiffener 330. In one aspect, the stiffener 330 may be associated to a ground reference voltage (Vss).

It is within the disclosure to affix the stiffener to the package substrate by using an adhesive, as shown, for example, in FIG. 5.

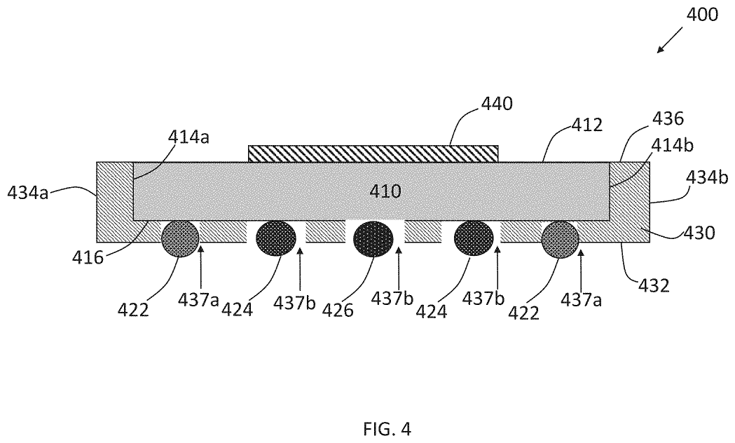

According to an aspect as illustrated in FIG. 4, the semiconductor package 400 may include components 410, 412, 414a, 414b, 416, 420, 430, 432, 434a, 434b, 436, 437a, 437b, 440 as analogously discussed for FIG. 2, wherein the plurality of solder balls 420 may include a first plurality of solder balls 422 associated with a ground reference voltage. The semiconductor package 400 may further include a second plurality of solder balls 424 associated with a power supply voltage. The semiconductor package 400 may further include a third plurality of solder balls 426 associated with signal data transmission. Depending on the electrical configuration of the stiffener 430, a first plurality of solder balls 422, a second plurality of solder balls 424, or a third plurality of solder balls 426 may be in contact with or may be spaced apart from the stiffener 430. In one aspect, the stiffener 430 may be associated to a ground reference voltage (Vss). In the same aspect, the first plurality of solder balls 422 may be in contact with the stiffener 430, meanwhile the second and third pluralities of solder balls 424, 426 may be spaced apart from the stiffener 430. The first, second and third pluralities of solder balls 422, 424 and 426 may be in contact with the bottom surface 416 of the package substrate 410.

It is within the disclosure to affix the stiffener to the package substrate by using an adhesive, as shown, for example, in FIG. 5.

According to an aspect as illustrated in FIG. 5, the semiconductor package 500 may include components 510, 512, 514a, 514b, 516, 520, 530, 532, 534a, 534b, 536, 537b, 540 as analogously discussed for FIG. 2, wherein an adhesive 550 may be used to affix the stiffener 530 to the substrate 510. The stiffener 530 can be affixed to the substrate 510 at selected or spot interface locations or continuously about an interface between the bottom surface 516 and the lateral sides 514 of the package substrate 510 and the stiffener 530, which can affect the bending stiffness of the semiconductor package 500. Any suitable adhesive (e.g., epoxy cement, alumina or silicate-based ceramic adhesive, urethane adhesive, polyimide adhesive, etc.) may be utilized, such as an electrically conductive and/or an electrically non-conductive adhesive. For example, an electrically conductive and/or non-conductive adhesive 550 may be used when the stiffener 530 is made of an electrically conductive material. In one aspect, an electrically conductive adhesive 550 can be disposed such that the adhesive 550 will be in contact with ground contact pads 590 on the package substrate 510 and the stiffener 530 to ground the stiffener and thereby enable the stiffener 530 to provide electromagnetic interference or radio-frequency interference shielding benefits when the stiffener 530 is made of an electrically conductive material. In an aspect, the ground (Vss) associated stiffener 530 may replace the first plurality of solder balls, e.g., the first plurality of solder balls 422 (in FIG. 4) for enhanced BGA density and/or package miniaturization.

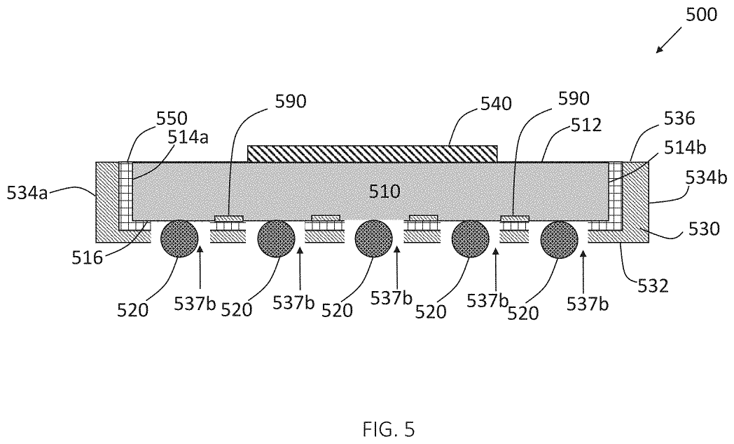

According to an aspect as illustrated in FIG. 6, the semiconductor package 600 may include components 610, 614, 620, 630, 637a, 637b, 650 as discussed for FIG. 2. The bottom portion (not shown) of the stiffener 630 may include a plurality of first openings 637a and a plurality of second openings 637b; and the plurality of solder balls 620 may further include solder balls coupled to the package substrate 610 extending at least partially through the openings 637a, 637b. FIG. 6 also shows the BGA 618 that is positioned in the plane of the bottom surface of the package substrate 610 and limited by lateral sides 614. The first openings 637a may have a first diameter that may range from 300 μm to 450 μm. The second openings 637b may have a second diameter greater than the first diameter. In an aspect, the second diameter may range from 480 μm to 550 μm. The first plurality of solder balls may be associated with a ground reference voltage. They may be disposed in the first opening 637a and may be in contact with the stiffener. Hence, the diameter of the solder ball of the first plurality of solder balls may be about the same or substantially the same diameter as the diameter of the first opening 637. This may be advantageous to provide electromagnetic interference shielding.

In one aspect, the second plurality of solder balls may be associated with a power supply voltage. They may be configured to facilitate power delivery and may be spaced apart from the stiffener 630 in the second opening 637b. The diameter of a solder ball in the second plurality of solder balls may be about the same or substantially the same diameter as the diameter of the solder ball of the first plurality of solder balls e.g., in the range of 300 μm to 450 μm. Hence, the spacing between a solder ball of the second plurality of solder balls and the stiffener may range from 30 μm to 250 μm.

In one aspect, the third plurality of solder balls may be associated with signal data transmission. They may be configured to be spaced apart from the stiffener 630 in the second opening 637b. The diameter of a solder ball in the third plurality of solder balls may be about the same or substantially the same diameter as the diameter of the solder ball of the first and second pluralities of solder balls e.g., in the range of 300 μm to 450 μm. Hence, the spacing between a solder ball of the third plurality of solder balls and the stiffener may range from approximately 30 μm to 250 μm.

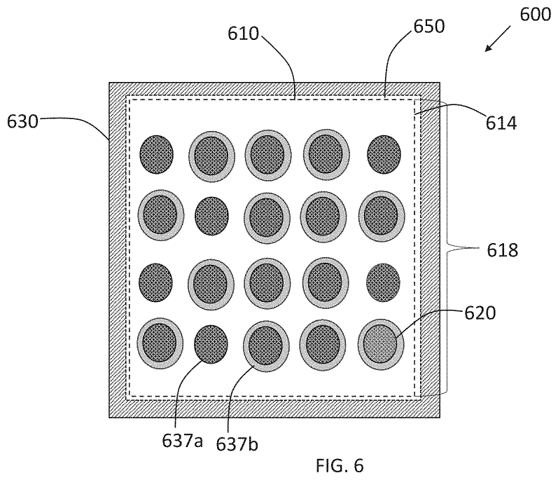

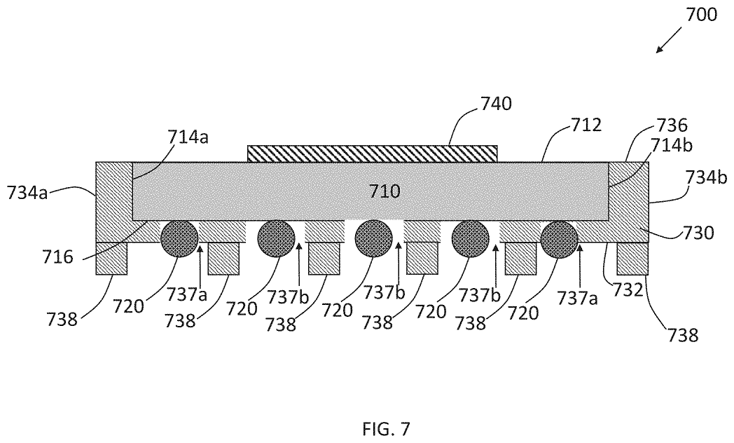

As illustrated in FIG. 7, the semiconductor package 700 may include components 710, 712, 714a, 714b, 716, 720, 730, 732, 734a, 734b, 736, 737a, 737b, 740 as analogously discussed for FIG. 2. In this aspect, the stiffener 730 may include a grounding portion 738 extending from the bottom portion 732 and disposed perpendicular to the bottom portion 732 and into a PCB, (not shown), optionally into a solder layer of the PCB. The grounding portion 738 may be in contact with the PCB. The grounding portion 738 may be provided in addition to first, second and third plurality of solder balls 720 or it may replace the first plurality of solder balls. The grounding portion 738 may be in the shape of a pillar. The grounding portion 738 may form a continuous array of pillars that extend between at least two or more adjacent solder balls 720. In other words, the grounding portion 738 may extend between one or more solder balls coupled to the package substrate in the ball grid array.

It is within the disclosure to affix the stiffener to the package substrate by using an adhesive, as shown, for example, in FIG. 5.

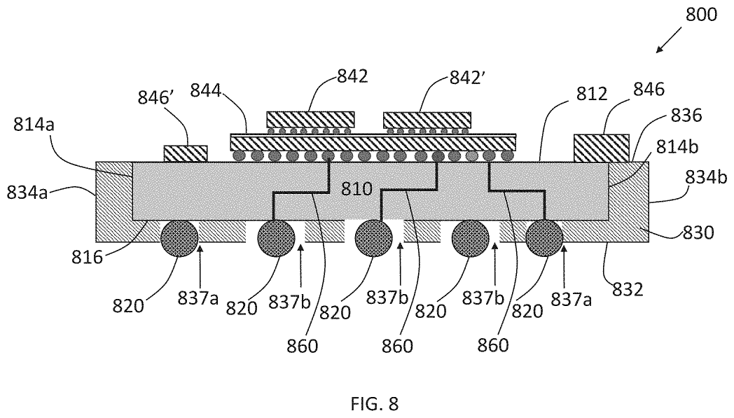

Further electrical components are shown in FIG. 8. In particular, the semiconductor package 800 may include components 810, 812, 814a, 814b, 816, 820, 830, 832, 834a, 834b, 836, 837a, 837b as analogously discussed for FIG. 2. The electrical components may include a first chiplet 842 and a second chiplet 842′. The first chiplet 842 and the second chiplet 842′ may be coupled with a silicon interposer 844, which is disposed on the top surface 812 of the package substrate 810. The electrical components may further include die-side capacitors 846 and 846′ that may be disposed on the top surface of the package substrate. The die-side capacitor 846 may be coupled to the stiffener 830 through, for example, a top surface 836 of the lateral portion 834 of the stiffener 830. The semiconductor package 800 may further include interconnect structures 860 for connecting the plurality of solder balls 820 to the electronic components 842, 842′, 844, 846, 846′.

It is within the disclosure to affix the stiffener to the package substrate by using an adhesive, as shown, for example, in FIG. 5.

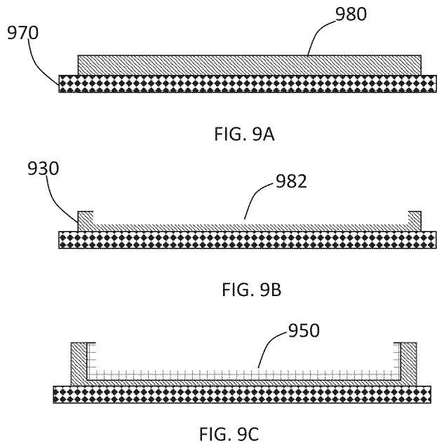

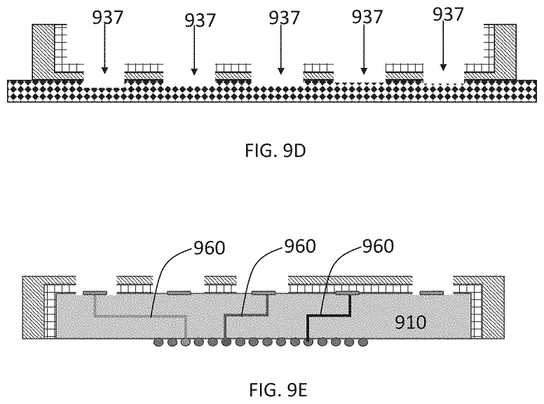

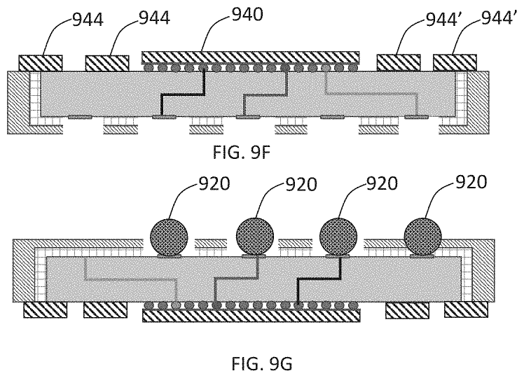

In another aspect, as illustrated in FIG. 9, there is provided a method including: forming a stiffener including a bottom portion and a lateral portion by first disposing a stiffener frame 980 on a carrier 970. The stiffener frame 980 may be attached to the carrier 970 by a hot-press or a lamination process (FIG. 9A). Subsequently, a stiffener cavity 982 may be formed by removing a portion of the stiffener frame 980 and thus forming the bottom portion and the lateral portion extending from the bottom portion of the stiffener 930. This removal may be carried out by, e.g., chemical etching, mechanical drilling (FIG. 9B). An adhesive 950 may be disposed on inner surfaces of the bottom portion and the lateral portion. This may be carried out, e.g., by hot-pressing, spin-coating, spraying and/or dispensing (FIG. 9C). Subsequently, a plurality of openings 937 may be formed in the bottom portion of the stiffener, e.g., by mechanical drilling and/or laser cutting (FIG. 9D). In FIG. 9E, the stiffener may be affixed to a package substrate 910, e.g., by hot-pressing, lamination and/or curing. During the affixing, the inner surface of the bottom portion of the stiffener may be affixed to a bottom surface of the package substrate and the inner surface of the lateral portion of the stiffener may be affixed to a lateral side of the package substrate. The package substrate may include interconnect structures 960. The top surface of the lateral portion may form a substantially flush surface with a top surface of the package substrate 910. In FIG. 9F, an electronic component 940, 944, 944′ may be coupled to a top surface of the package substrate; e.g., by solder reflow and/or a surface mount process. Subsequently, a plurality of solder balls 920 may be attached to a ball grid array arranged on the bottom surface by, e.g., solder reflowing and/or surface mounting (FIG. 9G).

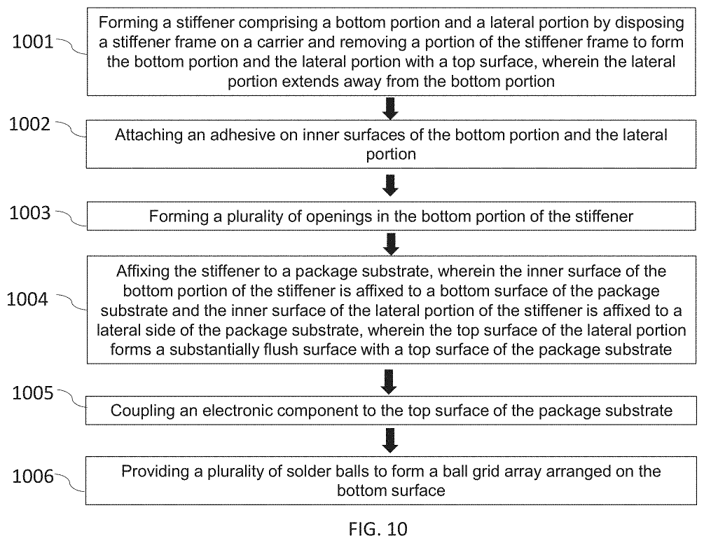

FIG. 10 shows a simplified flow diagram for an exemplary method for making a semiconductor package wherein a top surface of the package substrate is substantially flush with a top surface of a lateral portion of a stiffener according to an aspect of the present disclosure.

The operation 1001 may be directed to forming a stiffener comprising a bottom portion and a lateral portion by disposing a stiffener frame on a carrier and removing a portion of the stiffener frame to form the bottom portion and the lateral portion with a top surface, wherein the lateral portion extends away from the bottom portion.

The operation 1002 may be directed to attaching an adhesive on inner surfaces of the bottom portion and the lateral portion.

The operation 1003 may be directed to forming a plurality of openings in the bottom portion of the stiffener.

The operation 1004 may be directed to affixing the stiffener to a package substrate, wherein the inner surface of the bottom portion of the stiffener is affixed to a bottom surface of the package substrate and the inner surface of the lateral portion of the stiffener is affixed to a lateral side of the package substrate, wherein the top surface of the lateral portion forms a substantially flush surface with a top surface of the package substrate.

The operation 1005 may be directed to coupling an electronic component to the top surface of the package substrate.

The operation 1006 may be directed to providing a plurality of solder balls to form a ball grid array arranged on the bottom surface.

The fabrication methods and the choice of materials presented above are intended to be exemplary for forming the present semiconductor packages. It will be apparent to those ordinary skilled practitioners that the foregoing process operations may be modified without departing from the spirit of the present disclosure.

Further aspects of the disclosure and advantages described for the semiconductor package 200 of the previous aspect can be analogously valid for the method, and vice versa. As the various features, material properties and advantages have already been described above and in the examples demonstrated herein, they shall not be iterated for brevity where possible.

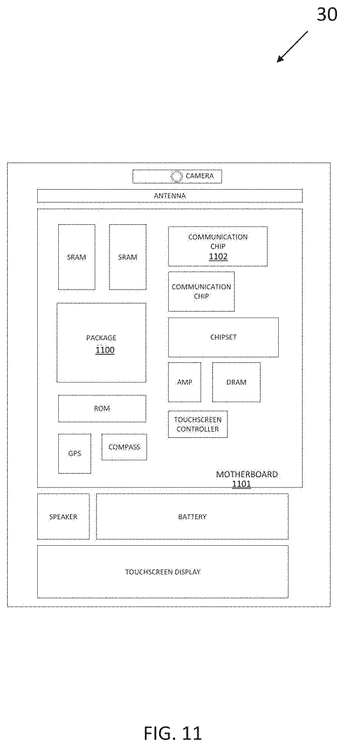

Aspects of the present disclosure may be implemented into a system using any suitable hardware and/or software. FIG. 11 schematically illustrates a computing device 30 that may include a semiconductor package as described herein, in accordance with some aspects. According to the present disclosure, the computer device 30 may include a printed circuit board, a semiconductor package, which has a package substrate with stiffener.

Accordingly, there may be provided a computing device. The computing device may include a motherboard; and a semiconductor package coupled to the motherboard. The semiconductor package may include: a package substrate including a top surface, lateral sides and a bottom surface; a ball grid array including a plurality of solder balls arranged on the bottom surface; a stiffener including a bottom portion affixed to the bottom surface of the package substrate and a lateral portion extending from the bottom portion and disposed about a lateral side of the package substrate such that the top surface of the package substrate is substantially flush with a top surface of the lateral portion; and an electronic component coupled to the top surface of the package substrate. The computing device may include a desktop computer, a laptop, a tablet, a smartphone, a wearable device, a server, or any combination thereof.

Further aspects of the disclosure and advantages described for the semiconductor package 200 of the previous aspect can be analogously valid for the computing device, and vice versa. As the various features, material properties and advantages have already been described above and in the examples demonstrated herein, they shall not be iterated for brevity where possible.

In another aspect, the computing device 30 may house a board such as a motherboard 1101. The motherboard 1101 may include a number of components, including, but not limited to, a semiconductor package 1100 and at least one communication chip 1102. The semiconductor package according to the present disclosure may be physically and electrically coupled to the motherboard 1101. In some implementations, the at least one communication chip 1102 may also be physically and electrically coupled to the motherboard 1101. In further implementations, the communication chip 1102 may be part of a semiconductor package.

Depending on its applications, computing device 30 may include other components that may or may not be physically and electrically coupled to the motherboard 1101. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 1100 of the computing device 30 may include a stiffener, as described herein.

The communication chip 1102 may enable wireless communications for the transfer of data to and from the computing device 30. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 1102 may implement any of a number of wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 1102 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1102 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1102 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1102 may operate in accordance with other wireless protocols in other aspects.

The computing device 30 may include a plurality of communication chips 1102. For instance, a first communication chip 1102 may be dedicated to shorter range wireless communications such as Wi-Fi and Bluetooth and a second communication chip 1102 may be dedicated to longer range wireless communications such as GPS, EDGE, GPRS, CDMA, WiMAX, LTE, Ev-DO, and others.

In various implementations, the computing device 30 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 30 may be a mobile computing device. In further implementations, the computing device 30 may be any other electronic device that processes data.

In a first example, there is provided a semiconductor package including: a package substrate including a top surface, lateral sides and a bottom surface; a ball grid array including a plurality of solder balls coupled to the bottom surface; a stiffener including a bottom portion affixed to the bottom surface of the package substrate and a lateral portion extending from the bottom portion and affixed to the lateral sides of the package substrate, the bottom portion of the stiffener including a plurality of openings for the plurality of solder balls, wherein the top surface of the package substrate is substantially flush with a top surface of the lateral portion; and an electronic component coupled to the top surface of the package substrate.

In a second example, the electronic component may include a passive component disposed on the top surface of the lateral portion.

In a third example, the plurality of solder balls may include a first plurality of solder balls associated with a ground reference voltage.

In a fourth example, the plurality of solder balls may include a second plurality of solder balls associated with a power supply voltage.

In a fifth example, the plurality of solder balls may include a third plurality of solder balls associated with signal data transmission.

In a sixth example, the passive component is selected from the group consisting of an inductor, a capacitor, a resistor, a voltage regulator, or any combination thereof.

In a seventh example, the bottom portion is affixed to the bottom surface of the package substrate with an adhesive.

In an eighth example, the plurality of openings for the plurality of solder balls may further include a first plurality of openings having a first diameter and a second plurality of openings having a second diameter greater than the first diameter.

In a ninth example, the first plurality of solder balls may contact the bottom portion of the stiffener to electrically couple the solder balls and the stiffener to provide electromagnetic interference shielding.

In a tenth example, the second plurality of solder balls and the third plurality of solder balls may be positioned in the openings spaced apart from the stiffener.

In an eleventh example, the bottom portion may include a thickness in a range of approximately 50 μm to 500 μm.

In a twelfth example, the stiffener may be constructed of a material including a metal material, a ceramic material, a polymer material, a composite material, or any combination thereof.

In a thirteenth example, the stiffener may be constructed of a non-conductive base material that is electroplated with a metal.

In a fourteenth example, the lateral portion may include a thickness in a range of approximately 50 μm to 500 μm.

In a fifteenth example, the stiffener may include a grounding portion extending perpendicular from the bottom portion into a printed circuit board.

In a sixteenth example, the grounding portion may extend between one or more of the plurality of solder balls coupled to the package substrate.

In a seventeenth example, there is provided a computing device, including: a motherboard; and a semiconductor package coupled to the motherboard, the semiconductor package including: a package substrate including a top surface, lateral sides and a bottom surface; a ball grid array including a plurality of solder balls coupled to the bottom surface; a stiffener including a bottom portion affixed to the bottom surface of the package substrate and a lateral portion extending from the bottom portion and affixed to the lateral sides of the package substrate, the bottom portion of the stiffener including a plurality of openings for the plurality of solder balls, wherein the top surface of the package substrate is substantially flush with a top surface of the lateral portion; and an electronic component coupled to the top surface of the package substrate.

In an eighteenth example, the electronic component may include a passive component disposed on the top surface of the lateral portion.

In a nineteenth example, there is provided method including: forming a stiffener including a bottom portion and a lateral portion by disposing a stiffener frame on a carrier and removing a portion of the stiffener frame to form the bottom portion and the lateral portion with a top surface, wherein the lateral portion may extend away from the bottom portion; attaching an adhesive on inner surfaces of the bottom portion and the lateral portion; forming a plurality of openings in the bottom portion of the stiffener; affixing the stiffener to a package substrate, wherein the inner surface of the bottom portion of the stiffener is affixed to a bottom surface of the package substrate and the inner surface of the lateral portion of the stiffener is affixed to a lateral side of the package substrate, wherein the top surface of the lateral portion forms a substantially flush surface with a top surface of the package substrate; coupling an electronic component to the top surface of the package substrate; and providing a plurality of solder balls to form a ball grid array arranged on the bottom surface.

In a twentieth example, the plurality of solder balls may include a first plurality of solder balls, a second plurality of solder balls and a third plurality of solder balls, wherein the first plurality of solder balls have a diameter that is different from a diameter of the second plurality of solder balls and a diameter of the third plurality of solder balls.

The dimensions of the semiconductor package and the choice of materials presented above are intended to be exemplary for forming the semiconductor package. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

By “about” or “approximately” in relation to a given numerical value, such as for thickness and height, it is meant to include numerical values within 10% of the specified value.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A semiconductor package comprising:
a package substrate comprising a top surface, lateral sides and a bottom surface;
a ball grid array comprising a plurality of solder balls coupled to the bottom surface;
a stiffener comprising a bottom portion affixed to the bottom surface of the package substrate and a lateral portion extending from the bottom portion and affixed to the lateral sides of the package substrate, the bottom portion of the stiffener comprising a plurality of openings for the plurality of solder balls, wherein the top surface of the package substrate is substantially flush with a top surface of the lateral portion; and
an electronic component coupled to the top surface of the package substrate.

2. The semiconductor package of claim 1, wherein the electronic component comprises a passive component disposed on the top surface of the lateral portion.

3. The semiconductor package of claim 1, wherein the plurality of solder balls comprises a first plurality of solder balls associated with a ground reference voltage.

4. The semiconductor package of claim 3, wherein the plurality of solder balls comprises a second plurality of solder balls associated with a power supply voltage.

5. The semiconductor package of claim 4, wherein the plurality of solder balls comprises a third plurality of solder balls associated with signal data transmission.

6. The semiconductor package of claim 2, wherein the passive component is selected from the group consisting of an inductor, a capacitor, a resistor, a voltage regulator, or any combination thereof.

7. The semiconductor package of claim 1, wherein the bottom portion is affixed to the bottom surface of the package substrate with an adhesive.

8. The semiconductor package of claim 1, wherein the plurality of openings for the plurality of solder balls further comprise a first plurality of openings having a first diameter and a second plurality of openings having a second diameter greater than the first diameter.

9. The semiconductor package of claim 3, wherein the first plurality of solder balls contact the bottom portion of the stiffener to electrically couple the solder balls and the stiffener to provide electromagnetic interference shielding.

10. The semiconductor package of claim 8, wherein the second plurality of solder balls and the third plurality of solder balls are positioned in the openings spaced apart from the stiffener.

11. The semiconductor package of claim 1, wherein the bottom portion comprises a thickness in a range of approximately 50 μm to 500 μm.

12. The semiconductor package of claim 1, wherein the stiffener is constructed of a material comprising a metal material, a ceramic material, a polymer material, a composite material, or any combination thereof.

13. The semiconductor package of claim 1, wherein the stiffener is constructed of a non-conductive base material that is electroplated with a metal.

14. The semiconductor package of claim 1, wherein the lateral portion comprises a thickness in a range of approximately 50 μm to 500 μm.

15. The semiconductor package of claim 1, wherein the stiffener comprises a grounding portion extending perpendicular from the bottom portion into a printed circuit board.

16. The semiconductor package of claim 15, wherein the grounding portion extends between one or more of the plurality of solder balls coupled to the package substrate.

17. A computing device, comprising:
a motherboard; and
a semiconductor package coupled to the motherboard, the semiconductor package comprising:
a package substrate comprising a top surface, lateral sides and a bottom surface;
a ball grid array comprising a plurality of solder balls coupled to the bottom surface;
a stiffener comprising a bottom portion affixed to the bottom surface of the package substrate and a lateral portion extending from the bottom portion and affixed to the lateral sides of the package substrate, the bottom portion of the stiffener comprising a plurality of openings for the plurality of solder balls, wherein the top surface of the package substrate is substantially flush with a top surface of the lateral portion; and
an electronic component coupled to the top surface of the package substrate.

18. The computing system of claim 17, wherein the electronic component comprises a passive component disposed on the top surface of the lateral portion.

19. A method comprising:
forming a stiffener comprising a bottom portion and a lateral portion by disposing a stiffener frame on a carrier and removing a portion of the stiffener frame to form the bottom portion and the lateral portion with a top surface, wherein the lateral portion extends away from the bottom portion;
attaching an adhesive on inner surfaces of the bottom portion and the lateral portion;
forming a plurality of openings in the bottom portion of the stiffener;
affixing the stiffener to a package substrate, wherein the inner surface of the bottom portion of the stiffener is affixed to a bottom surface of the package substrate and the inner surface of the lateral portion of the stiffener is affixed to a lateral side of the package substrate, wherein the top surface of the lateral portion forms a substantially flush surface with a top surface of the package substrate;
coupling an electronic component to the top surface of the package substrate; and providing a plurality of solder balls to form a ball grid array arranged on the bottom surface.

20. The method of claim 19, wherein the plurality of solder balls comprises a first plurality of solder balls, a second plurality of solder balls and a third plurality of solder balls, wherein the first plurality of solder balls have a diameter that is different from a diameter of the second plurality of solder balls and a diameter of the third plurality of solder balls.
